(19) United States
(12) Patent Application Publication
(10) Pub. No.: US 2023/0387376 A1
(43) Pub. Date: Nov. 30, 2023

(54) APPARATUS, SYSTEM, AND METHOD FOR ACHIEVING BRIGHTNESS UNIFORMITY ACROSS DISPLAY ELEMENTS

(71) Applicant: Facebook Technologies, LLC, Menlo Park, CA (US)

(72) Inventor: Alex Ockfen, Bothell, WA (US)

(21) Appl. No.: 17/824,242

(22) Filed: May 25, 2022

(51) Int. Cl. H01L 33/64; H01L 25/075; G02B 27/01; H05K 7/20

(52) U.S. Cl. CPC H01L 33/641; H01L 25/0753; G02B 27/0176; H05K 7/2099; H01L 2933/0075

(57) ABSTRACT

A display device comprising (1) a substrate, (2) a set of display elements disposed on the substrate and configured to emit light for presentation to a user, and (3) a phase-change material applied to the substrate or the set of display elements, wherein the phase-change material is configured to store thermal energy generated by the set of display elements. Various other apparatuses, devices, systems, and methods are also disclosed.

### BRIEF DESCRIPTION OF DRAWINGS

The accompanying drawings illustrate a number of exemplary embodiments and are parts of the specification. Together with the following description, the drawings demonstrate and explain various principles of the instant disclosure.

FIG. 1 is an illustration of an exemplary display device that facilitates achieving brightness uniformity across display elements according to one or more embodiments of this disclosure.

FIG. 2 is an illustration of an exemplary display element that incorporates phase-change material for storing thermal energy according to one or more embodiments of this disclosure.

FIG. 3 is an illustration of an exemplary substrate that incorporates phase-change material for storing thermal energy according to one or more embodiments of this disclosure.

FIG. 4 is an illustration of an exemplary substrate that incorporates phase-change material for storing thermal energy according to one or more embodiments of this disclosure.

FIG. 5 is an illustration of an exemplary substrate that incorporates phase-change material for storing thermal energy according to one or more embodiments of this disclosure.

FIG. 6 is an illustration of an exemplary display device that facilitates achieving brightness uniformity across display elements according to one or more embodiments of this disclosure.

FIG. 7 is an illustration of an exemplary display device that facilitates achieving brightness uniformity across display elements according to one or more embodiments of this disclosure.

FIG. 8 is a flowchart of an exemplary method for achieving brightness uniformity across display elements according to one or more embodiments of this disclosure.

FIG. 9 is an illustration of an exemplary profile of a phase-change material incorporated into a display device for storing thermal energy according to one or more embodiments of this disclosure.

FIG. 10 is an illustration of exemplary augmented-reality glasses that may be used in connection with embodiments of this disclosure.

FIG. 11 is an illustration of an exemplary virtual-reality headset that may be used in connection with embodiments of this disclosure.

While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, combinations, equivalents, and alternatives falling within this disclosure.

### DETAILED DESCRIPTION

The present disclosure is generally directed to apparatuses, systems, and methods for achieving brightness uniformity across display elements. As will be explained in greater detail below, these apparatuses, systems, and methods may provide numerous features and benefits.

Some display devices may include and/or represent various display elements with sensitivities and/or susceptibilities that lead to instances of low brightness and/or non-uniform brightness. For example, augmented-reality (AR) glasses may include and/or implement a display driven by microscopic light-emitting diodes (microLEDs). The brightness of such microLEDs may be sensitive and/or susceptible to temperature variations. Specifically, as the temperature of the microLEDs increases, the brightness of the microLEDs may diminish and/or decrease, thus leading to inconsistent and/or unreliable brightness from the microLEDs. Unfortunately, the inconsistent and/or unreliable brightness of the microLEDs may impair and/or inhibit the performance of the AR glasses as well as the believability of the user's AR experience.

Moreover, at any given time during a user's AR session, the temperatures of the microLEDs may vary from one to the next due to numerous factors (e.g., display content, frequency of use, etc.), potentially resulting in brightness discrepancies and/or non-uniformities across the microLEDs in the display. Unfortunately, the brightness discrepancies and/or non-uniformities across the microLEDs in the display may further impair and/or inhibit the performance of the AR glasses as well as the believability of the user's AR experience. To combat and/or address such brightness discrepancies and/or non-uniformities, some AR equipment designers and/or vendors may limit and/or restrict the display to the brightness of the dimmest microLED at any given time. The instant disclosure, therefore, identifies and addresses a need for achieving brightness consistency and/or uniformity across display elements without controlled dimming.

As will be discussed in greater detail below, the apparatuses, systems, and methods disclosed herein may enable displays to achieve brightness consistency and/or uniformity across various display elements without controlled dimming. For example, a pair of AR glasses may include and/or implement a microLED display embedded with phase-change materials that store thermal energy. In this example, the phase-change materials may be configured and/or intended to store thermal energy generated by the microLED display without increasing temperature during a phase transition (e.g., a transition from a solid state to a liquid state). In other words, the phase-change materials may be able to absorb and/or capture significant amounts of heat generated by the microLED display while maintaining a substantially constant and/or unchanging temperature. As a result, the microLEDs may operate at lower temperatures that do not diminish and/or decrease the brightness of the emitted light.

By doing so, the phase-change materials may enable the microLEDs included in the display to achieve and/or maintain consistent and/or reliable brightness despite generating significant amounts of thermal energy. As a result, the display may be able to achieve and/or maintain brightness uniformity across the microLEDs even though the brightness of the microLEDs remains sensitive and/or susceptible to temperature variations.

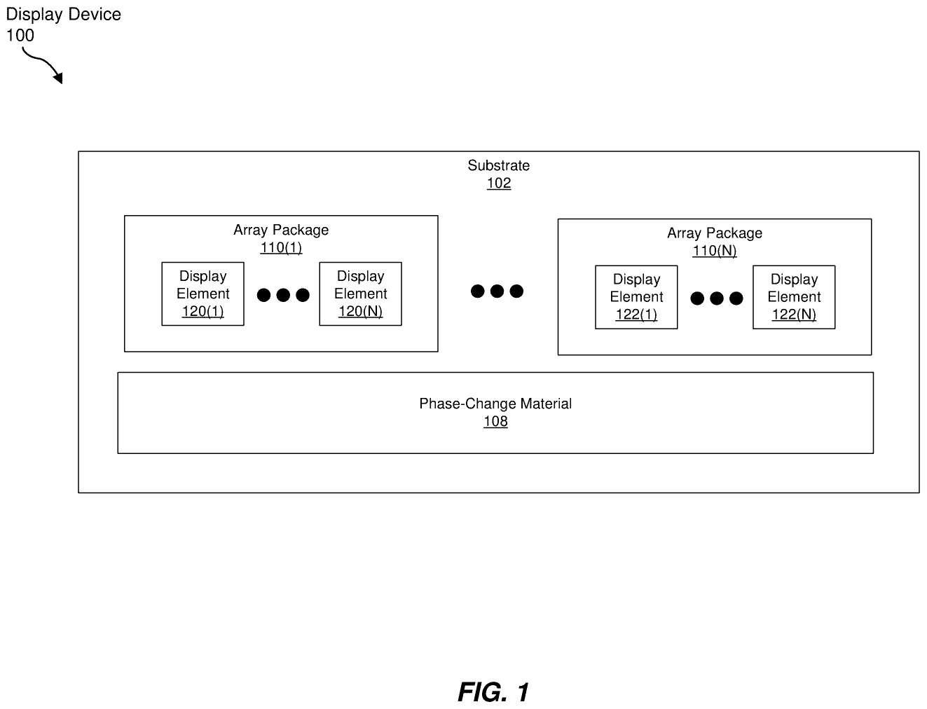

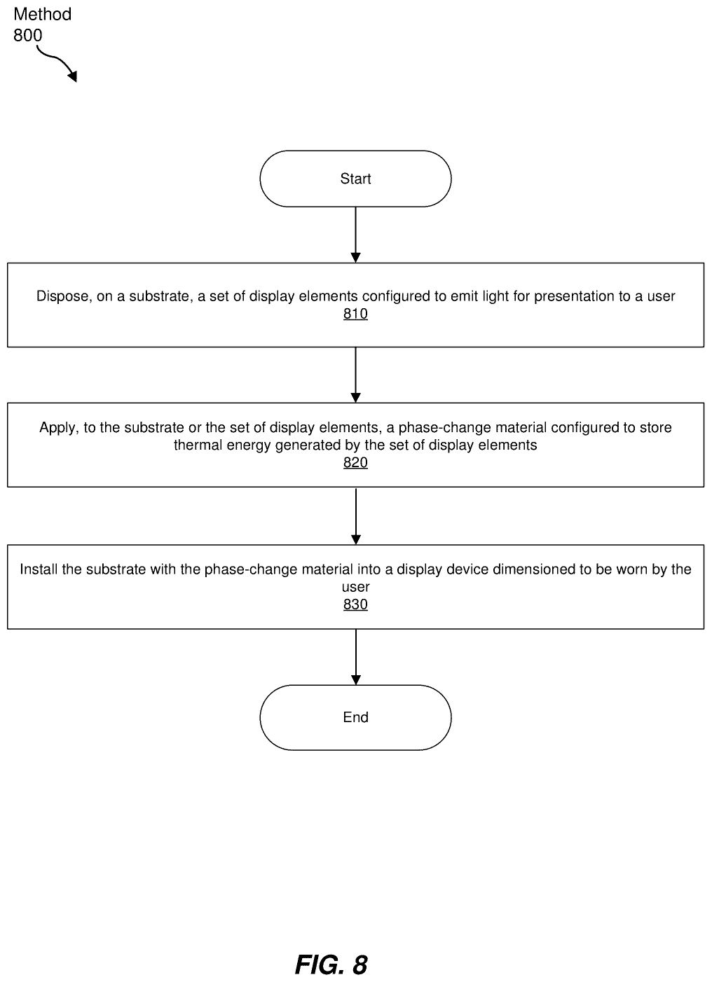

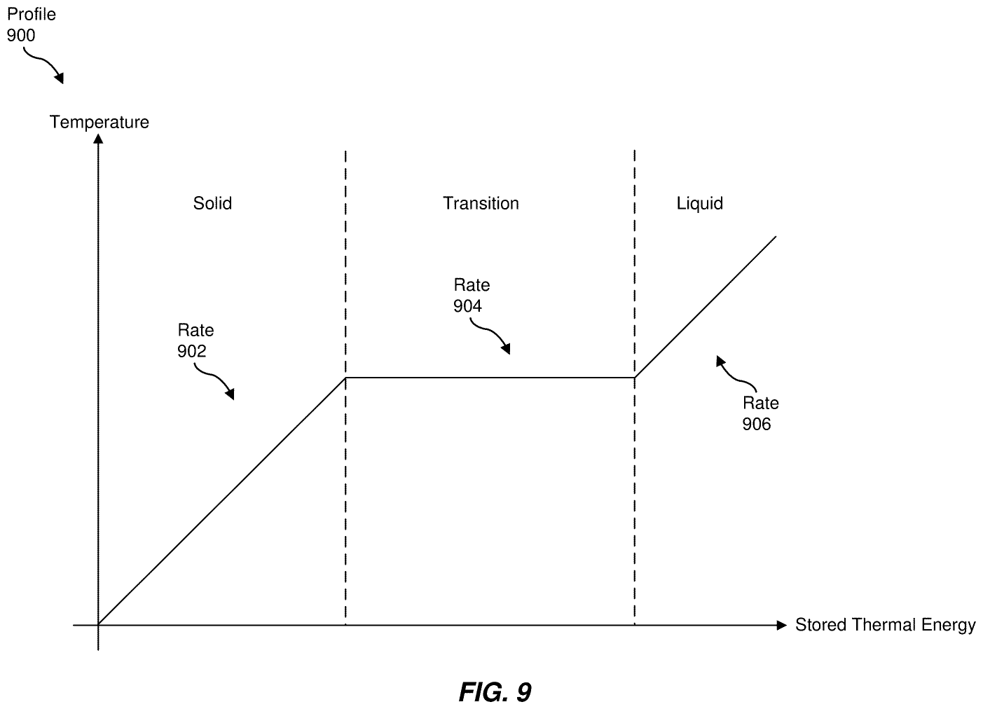

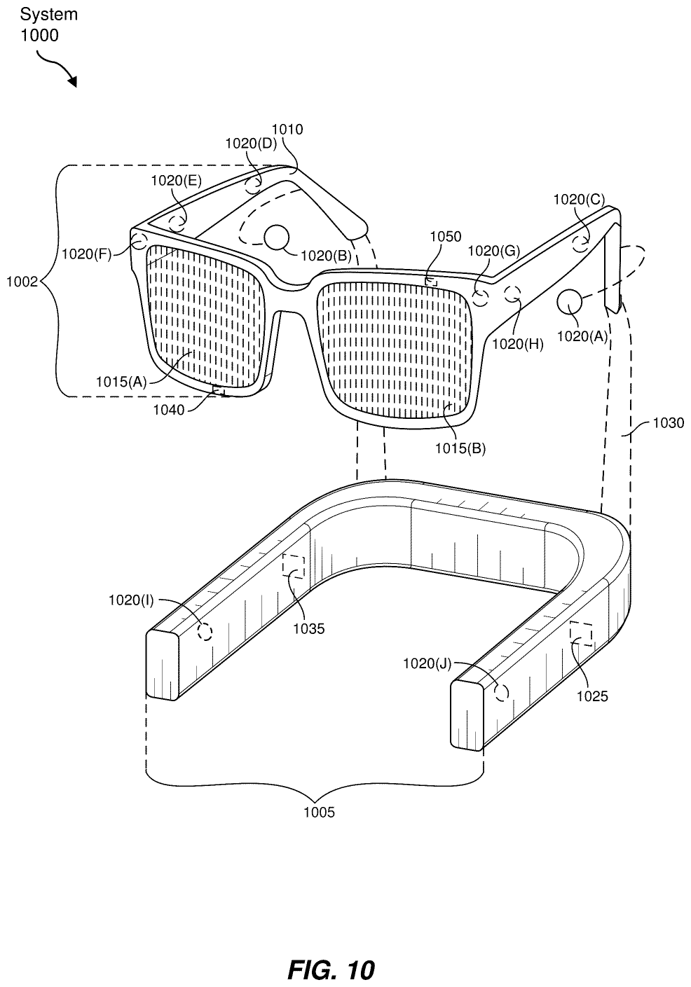

The following will provide, with reference to FIGS. 1-7, detailed descriptions of exemplary devices, systems, components, and corresponding implementations for achieving brightness uniformity across display elements. In addition, detailed descriptions of methods for achieving brightness uniformity across display elements will be provided in connection with FIG. 8. The discussion corresponding to FIGS. 9 and 10 will provide detailed descriptions of types of exemplary artificial-reality devices, wearables, and/or associated systems capable of achieving brightness uniformity across display elements.

FIG. 1 illustrates a portion of an exemplary display device 100 that includes and/or represents a substrate 102, one or more array packages 110(1)-(N), and/or a phase-change material 108. In some examples, array packages 110(1)-(N) may include and/or represent display elements 120(1)-(N) and 122(1)-(N), respectively. In such examples, display elements 120(1)-(N) and 122(1)-(N) may be configured and/or designed to emit and/or generate light for presentation to a user of display device 100. In one example, array packages 110(1)-(N) may be disposed and/or arranged on substrate 102.

In some examples, phase-change material 108 may be applied to and/or embedded in substrate 102, array packages 110(1)-(N), display elements 120(1)-(N), and/or display elements 122(1)-(N). In such examples, phase-change material 108 may be configured, intended, and/or tuned to store thermal energy without increasing temperature during a phase transition. In other words, phase-change material 108 may be able to absorb and/or capture significant amounts of thermal energy generated by display elements 120(1)-(N) and/or 122(1)-(N) while maintaining a substantially constant and/or unchanging temperature during the phase transition. As a result, phase-change material 108 may serve to cool display elements 120(1)-(N) and/or 122(1)-(N) such that they are able to operate at lower temperatures that do not diminish and/or decrease the brightness of the emitted light.

In some examples, phase-change material 108 may be configured to experience a temperature change at a first rate while in a fundamental state (e.g., a solid state or a liquid state) as the amount of thermal energy stored increases or decreases. For example, as phase-change material 108 stores more thermal energy in a solid state, the temperature of phase-change material 108 may increase at a first rate. Likewise, as phase-change material 108 stores less (by, e.g., releasing) thermal energy in the solid state, the temperature of phase-change material 108 may decrease at the first rate. In one example, this first rate may cause the temperature of phase-change material 108 to increase or decrease proportionate to and/or commensurate with the amount of thermal energy stored by phase-change material 108.

In some examples, phase-change material 108 may be configured to experience a temperature change at a second rate while in a phase transition (e.g., transitioning from a solid state to a liquid state or vice versa) as the amount of thermal energy stored increases or decreases. For example, as phase-change material 108 stores more thermal energy during a phase transition, the temperature of phase-change material 108 may increase at a second rate that differs from the first rate. Likewise, as phase-change material 108 stores less (by, e.g., releasing) thermal energy during the phase transition, the temperature of phase-change material 108 may decrease at the second rate. In one example, this second rate may cause the temperature of phase-change material 108 to increase or decrease disproportionate to and/or incommensurate with the amount of thermal energy stored by phase-change material 108.

In some examples, the first rate at which phase-change material 108 experiences a temperature change in a fundamental state may be higher than the second rate at which phase-change material 108 experiences a temperature change during a phase transition. For example, in the fundamental state, the temperature of phase-change material 108 may increase as phase-change material 108 stores more thermal energy. However, during the phase transition, the temperature of phase-change material 108 may remain substantially static and/or unchanged as phase-change material 108 stores more thermal energy.

In one example, depending on the type and/or characteristics of phase-change material 108, the temperature of phase-change material 108 may increase nominally and/or moderately as phase-change material 108 stores more thermal energy during the phase transition. However, in this example, the amount of temperature increase experienced by phase-change material 108 during the phase transition may be less and/or lower than the amount of temperature increase that would have been experienced by phase-change material 108 in the fundamental state under the same and/or comparable conditions. For example, if phase-change material 108 absorbs and/or captures 100 joules of thermal energy in the fundamental state, the temperature of phase-change material 108 may increase by approximately 50 degrees Celsius. In contrast, if phase-change material 108 absorbs and/or captures 100 more joules of thermal energy during the phase transition, the temperature of phase-change material 108 may increase by anywhere from 0 to 5 degrees Celsius. Accordingly, the temperature-to-energy ratio of phase-change material 108 in the fundamental state may be significantly higher than the temperature-to-energy ratio of phase-change material 108 during the phase transition.

In some examples, phase-change material 108 may include and/or represent any type or form of substance, material, compound, and/or component that experiences different temperature-change rates relative to the amount of thermal energy stored, absorbed, and/or captured over different states and/or phase transitions. In one example, phase-change material 108 may include and/or represent any of a variety of waxes that exhibit phase-change characteristics. In this example, the wax may store, absorb, and/or capture a significant amount of thermal energy while maintaining a substantially static temperature during a phase transition. Additional examples of phase-change material 108 include, without limitation, organic phase-change materials, inorganic phase-change materials, eutectic phase-change materials, paraffins, lipids, sugar alcohols, salt hydrates, waxy substances, combinations or variations of one or more of the same, and/or any other suitable phase-change material.

In some examples, phase-change material 108 may experience different states depending on the amount of thermal energy stored, absorbed, captured, and/or applied. In one example, phase-change material 108 may experience, form, and/or represent different fundamental and/or classical states of matter, including a solid state, a liquid state, a gaseous state, and/or a plasma state. Additionally or alternatively, phase-change material 108 may experience, form, and/or represent a transitional state and/or phase as phase-change material 108 transitions and/or transforms from one fundamental and/or classical state to another. Such transitional states and/or phases may include and/or represent melting, liquifying, solidifying, vaporizing, and/or condensing.

In some examples, substrate 102 may include and/or represent one or more circuit boards and/or electrical packages that facilitate carrying and/or transferring electric current and/or signals. In one example, each circuit board and/or electrical package in substrate 102 may include and/or represent one or more planes and/or layers through which electric current and/or signals are able to pass and/or traverse.

In some examples, substrate 102 may include and/or contain a variety of materials. Some of these materials may conduct electricity. Other materials included in substrate 102 may insulate certain conductive materials from one another.

In some examples, substrate 102 may include and/or incorporate various electrically conductive layers, such as ground layers, power layers, and/or signal layers. In one example, each electrically conductive layer may include and/or represent a plane of conductive material that is etched during the fabrication phase to produce various conductive paths and/or traces throughout substrate 102. In this example, the etched conductive paths and/or traces may be separated from and/or interconnected with one another as necessary to form one or more portions of a circuit that incorporate electrical components and/or electronics across substrate 102. Examples of such electrically conductive materials include, without limitation, copper, aluminum, silver, gold, alloys of one or more of the same, combinations or variations of one or more of the same, and/or any other suitable materials.

In some examples, substrate 102 may include and/or incorporate insulating material that facilitates mounting (e.g., mechanical support) and/or interconnection (e.g., electrical coupling) of electrical and/or electronic components. In one example, substrate 102 may include and/or represent one or more printed circuit boards (PCBs). Various components may be laminated, etched, attached, and/or otherwise coupled to substrate 102.

In some examples, substrate 102 may include and/or represent insulation material that electrically insulates different planes, layers, and/or signals from one another. In some examples, the insulation material may constitute and/or represent a dielectric substance that is a poor conductor of electricity and/or is polarized by an applied electric field. In one example, dielectric substances may be implemented as solids, liquids, and/or gases. Examples of dielectric substances include, without limitation, porcelains, glasses, plastics, industrial coatings, silicon, germanium, gallium arsenide, mica, metal oxides, silicon dioxides, sapphires, aluminum oxides, polymers, ceramics, variations or combinations of one or more of the same, and/or any other suitable dielectric materials.

In some examples, substrate 102 may be fabricated in any of a variety of ways, including sequential lamination. For example, as part of a sequential lamination process, substrate 102 may be fabricated layer by layer, using certain subcomposites of copper and insulating materials. In this example, the sequential lamination process may facilitate trace routing and/or via drilling within internal planes and/or layers.

In some examples, substrate 102 may form and/or represent an integrated circuit with various electrical contacts that facilitate electrical couplings. In some examples, such electrical contacts may be disposed on, along, and/or through the integrated circuit. In one example, substrate 102 may be packaged and/or arranged in a land grid array (LGA) form factor. In another example, substrate 102 may be packaged and/or arranged in a ball grid array (BGA) form factor. Additionally or alternatively, substrate 102 may be packaged and/or arranged in any other suitable form factor, including surface mount form factors, flat package form factors, small outline form factors, chip-scale form factors, quad row form factors, multi-chip form factors, combinations or variations of one or more of the same, and/or any other suitable form factors.

In some examples, display elements 120(1)-(N) and/or 122(1)-(N) may include and/or represent any type or form of device and/or component capable of emitting light for illuminating a visual display and/or displaying visual content. In one example, display elements 120(1)-(N) and/or 122(1)-(N) may each include and/or represent a microLED. Additional examples of display elements 120(1)-(N) and/or 122(1)-(N) include, without limitation, pixels, laser diodes, laser projectors, light-emitting diodes (LEDs), organic LEDs (OLEDs), liquid crystal displays (LCDs), light-emitting devices, combinations or variations of one or more of the same, and/or any other suitable display elements. Display elements 120(1)-(N) and/or 122(1)-(N) may be driven and/or stimulated to produce and/or emit visible light by applying electric current.

In some examples, display elements 120(1)-(N) may be arranged and/or organized in array package 110(1), and display elements 122(1)-(N) may be arranged and/or organized in array package 110(N). In such examples, array packages 110(1)-(N) may each include and/or represent an integrated circuit and/or a certain form factor. In one example, array packages 110(1)-(N) may each include and/or represent display elements of different colors. For example, array package 110(1) may include and/or represent a set of microLEDs that all emit and/or produce light of a certain color, and array package 110(N) may include and/or represent another set of microLEDs that all emit and/or produce light of a different color. Accordingly, array packages 110(1)-(N) may each include and/or represent a color-specific array, matrix, and/or packaging of display elements.

In some examples, display device 100 may include and/or represent any type or form of device, system, and/or component that displays and/or presents visual and/or optical content for viewing by a user. In one example, display device 100 may include and/or represent an artificial-reality headset and/or head-mounted display (HMD). For example, display device 100 may include and/or represent an AR headset, a virtual reality headset, a mixed reality headset, a hybrid reality headset, or the like. Additional examples of display device 100 include, without limitation, televisions, monitors, touch screens, embedded displays, LCD displays, microLED displays, LED displays, plasma displays, combinations or variations of one or more of the same, and/or any other suitable display device 100.

As will be described in greater detail below, phase-change material 108 may be applied and/or incorporated into substrate 102, array packages 110(1)-(N), and/or display elements 120(1)-(N) or 122(1)-(N) in a variety of different ways and/or contexts. For example, phase-change material 108 may be applied and/or incorporated into one or more of display elements 120(1)-(N) and/or 122(1)-(N). Additionally or alternatively, phase-change material 108 may be applied and/or incorporated into one or more of array packages 110(1)-(N) and/or substrate 102.

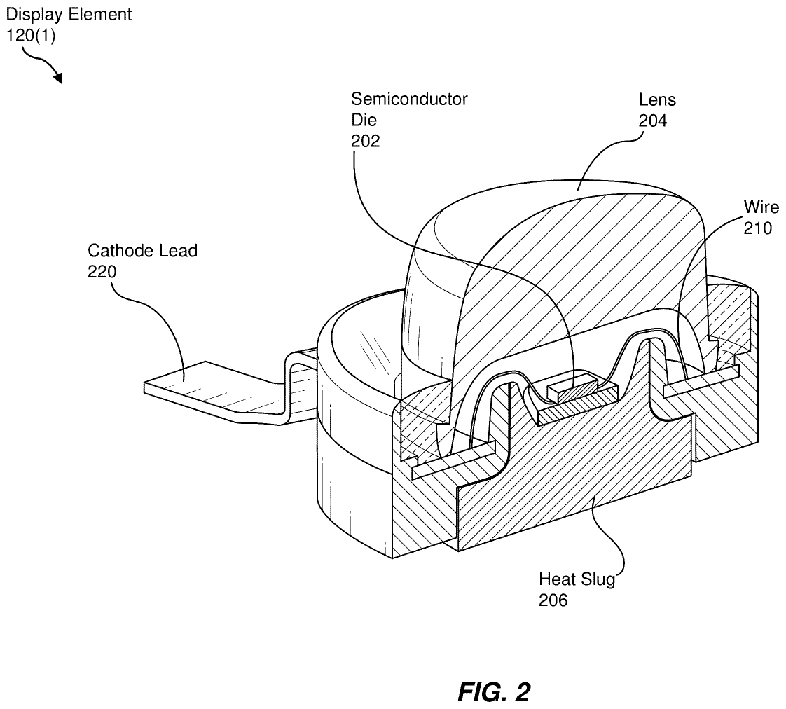

FIG. 2 illustrates an exemplary display element 120(1) that emits and/or produce light. As illustrated, display element 120(1) may include and/or represent a semiconductor die 202, a lens 204, a heat slug 206, a wire 210, and/or a cathode lead 220. In some examples, semiconductor die 202 may include and/or represent the active element and/or component that emits and/or produces visible light when stimulated by electric current carried by wire 210. In one example, semiconductor die 202 may be mounted and/or positioned between lens 204 and heat slug 206. In this example, phase-change material 108 may form, constitute, and/or represent all or a portion of heat slug 206.

In some examples, phase-change material 108 in heat slug 206 may store thermal energy generated by semiconductor die 202 without significantly increasing in temperature during a phase transition (e.g., a transition from a solid state to a liquid state). In other words, phase-change material 108 in heat slug 206 may be able to absorb and/or capture significant amounts of heat generated by semiconductor die 202 while maintaining a substantially constant and/or unchanging temperature during the phase transition. As a result, semiconductor die 202 and/or display element 120(1) may operate at lower temperatures that do not diminish and/or decrease the brightness of the emitted light. By doing so, phase-change material 108 in heat slug 206 may enable semiconductor die 202 and/or display element 120(1) to achieve and/or maintain consistent and/or reliable brightness despite generating significant amounts of thermal energy.

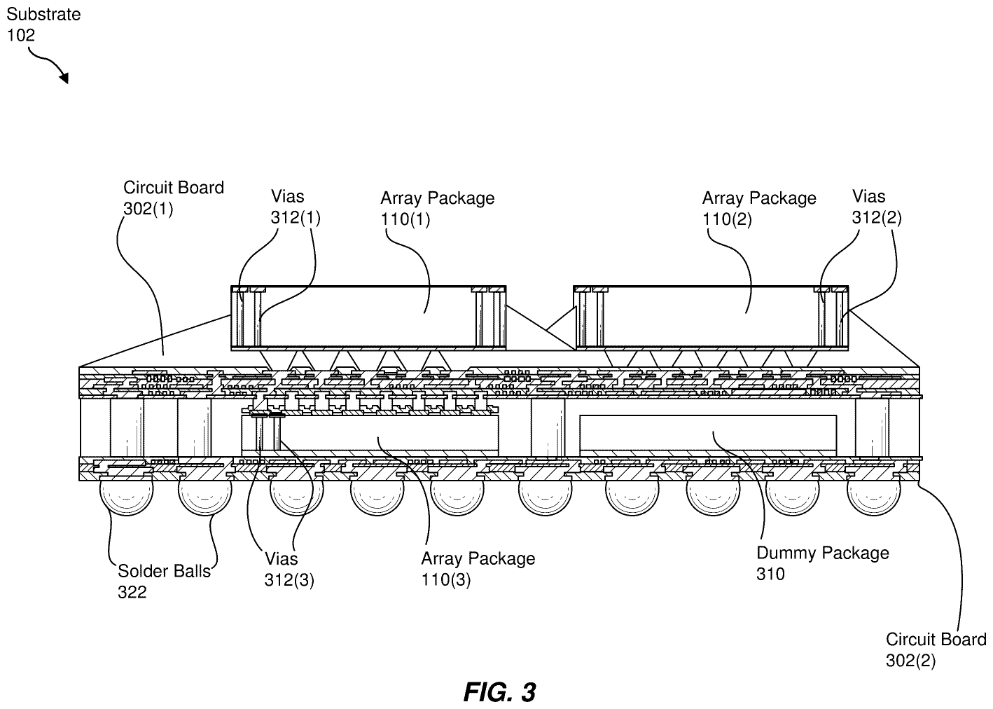

FIGS. 3-5 illustrate different exemplary implementations of exemplary substrate 102 in which phase-change material 108 is applied to achieve brightness uniformity across display elements. As illustrated in FIGS. 3-5, exemplary substrate 102 may include and/or represent circuit boards 302(1) and 302(2), solder balls 322, and/or array packages 110(1), 110(2), and 110(3). In some examples, circuit boards 302(1) and 302(2) may be coupled and/or secured to one another. For example, circuit boards 302(1) and 302(2) may be vertically attached to and/or stacked atop one another. In one example, array packages 110(1) and 110(2) may be positioned and/or installed on one side of circuit board 302(1). In this example, array packages 110(1) and 110(2) may be electrically and/or communicatively coupled to that side of circuit board 302(1) such that electrical continuity exists and/or is formed between circuit board 302(1) and array packages 110(1)-(2).

In some examples, array package 110(3) may be positioned and/or installed between circuit boards 302(1) and 302(2). Accordingly, array package 110(3) may be positioned and/or installed on the other side of circuit board 302(1) relative to array packages 110(1) and 110(2). In one example, array package 110(3) may be electrically and/or communicatively coupled to that side of circuit board 302(1) such that electrical continuity exists and/or is formed between circuit board 302(1) and array package 110(3). Additionally or alternatively, array package 110(3) may be positioned and/or installed on one side of circuit board 302(2) opposite solder balls 322. In this example, array package 110(3) may be electrically and/or communicatively coupled to that side of circuit board 302(2) such that electrical continuity exists and/or is formed between circuit board 302(2) and array package 110(3).

In some examples, array packages 110(1)-(3) may each correspond to and/or represent a color-specific array, matrix, and/or packaging of display elements. For example, array package 110(1) may include and/or represent only display elements that emit and/or produce blue-colored light. In this example, array package 110(2) may include and/or represent only display elements that emit and/or produce red-colored light, and array package 110(3) may include and/or represent only display elements that emit and/or produce green-colored light. Together, array packages 110(1)-(3) may include and/or represent an RGB color modeling system capable of forming and/or producing a broad range of colors when combined in specific ways.

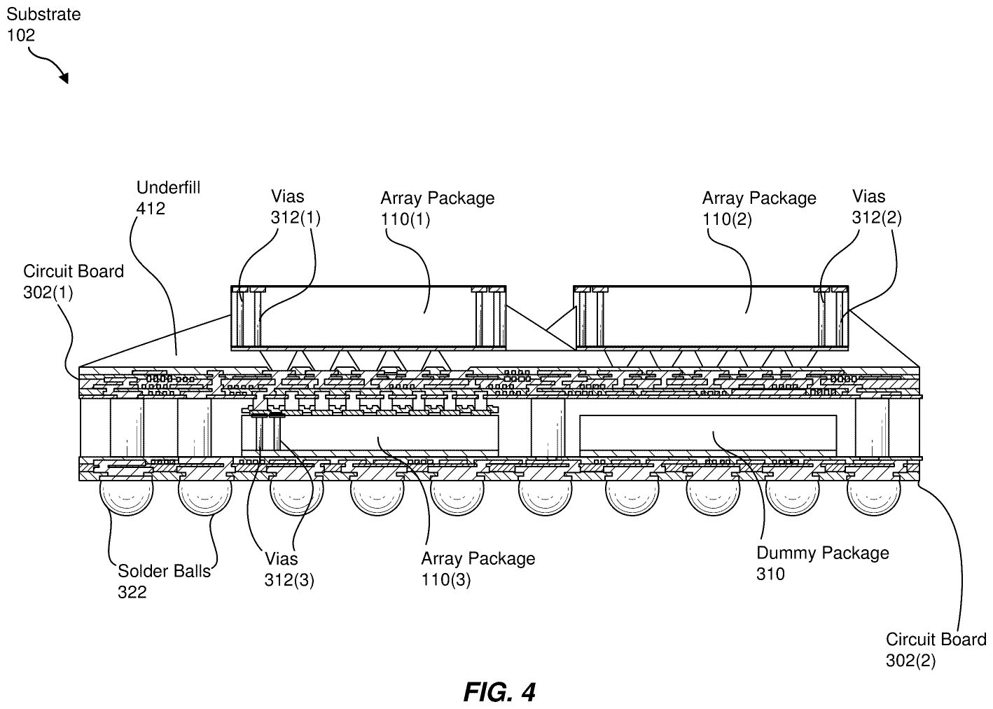

As illustrated in FIGS. 3 and 4, exemplary substrate 102 may include and/or represent a dummy package 310 that balances out the design and/or symmetry of substrate 102. In some examples, dummy package 310 may serve a passive role (e.g., a non-electrical and/or non-optical role) in the construction and/or functionality of substrate 102. In such examples, unlike array packages 110(1)-(3), dummy package 310 may fail to include and/or provide any display elements that emit and/or produce light.

In FIG. 3, the implementation of substrate 102 may include and/or incorporate phase-change material 108 in one or more of array packages 110(1)-(3). For example, array packages 110(1)-(3) may include and/or form vias 312(1), 312(2), and/or 312(3), respectively. In this example, one or more of vias 312(1)-(3) may include and/or represent a thermal via that stores, absorbs, and/or captures thermal energy. Additionally or alternatively, one or more of vias 312(1)-(3) may include and/or represent an electrical via that provides and/or forms electrical continuity from one layer and/or side to another layer and/or side. Accordingly, one or more of vias 312(1)-(3) may provide and/or serve the dual purpose of transferring current or electrical signals and/or storing thermal energy.

In some examples, each via may include and/or represent a hole drilled and/or formed in an array package. In one example, the hole may be wholly and/or partially plated with electrically conductive material to create and/or form a conductive path and/or bridge across one or more of layers and/or planes of the array package. Additionally or alternatively, the hole may be wholly and/or partially filled and/or packed with phase-change material 108.

In some examples, phase-change material 108 may fill and/or occupy one or more of vias 312(1)-(3). In such examples, phase-change material 108 in vias 312(1)-(3) may store thermal energy generated by one or more display elements disposed on array packages 110(1)-(3) without significantly increasing in temperature during a phase transition (e.g., a transition from a solid state to a liquid state). In other words, phase-change material 108 in vias 312(1)-(3) may be able to absorb and/or capture significant amounts of heat generated by such display elements while maintaining a substantially constant and/or unchanging temperature during the phase transition. As a result, these display elements may operate at lower temperatures that do not diminish and/or decrease the brightness of the emitted light. By doing so, phase-change material 108 in vias 312(1)-(3) may enable these display elements to achieve and/or maintain consistent and/or reliable brightness despite generating significant amounts of thermal energy. As a result, array packages 110(1)-(3) may be able to achieve and/or maintain brightness uniformity across their respective display elements even though the brightness of such display elements is sensitive and/or susceptible to temperature changes.

In FIG. 4, the implementation of substrate 102 may include and/or incorporate phase-change material 108 in an underfill 412 applied and/or installed between array packages 110(1)-(2) and circuit board 302(1). In some examples, phase-change material 108 may form all or a portion of underfill 412. In one example, underfill 412 may include and/or represent an adhesive, a coating, and/or a film. In this example, underfill 412 may include and/or represent one or more beads, drops, and/or globules of phase-change material 108 that are incorporated into the adhesive, coating, and/or film.

In some examples, phase-change material 108 in underfill 412 may store thermal energy generated by one or more display elements incorporated in array packages 110(1)-(2) without significantly increasing in temperature during a phase transition (e.g., a transition from a solid state to a liquid state). In other words, phase-change material 108 in underfill 412 may be able to absorb and/or capture significant amounts of heat generated by such display elements while maintaining a substantially constant and/or unchanging temperature during the phase transition. As a result, these display elements may operate at lower temperatures that do not diminish and/or decrease the brightness of the emitted light. By doing so, phase-change material 108 in underfill 412 may enable these display elements to achieve and/or maintain consistent and/or reliable brightness despite generating significant amounts of thermal energy. As a result, array packages 110(1)-(2) may be able to achieve and/or maintain brightness uniformity across their respective display elements even though the brightness of such display elements is sensitive and/or susceptible to temperature changes.

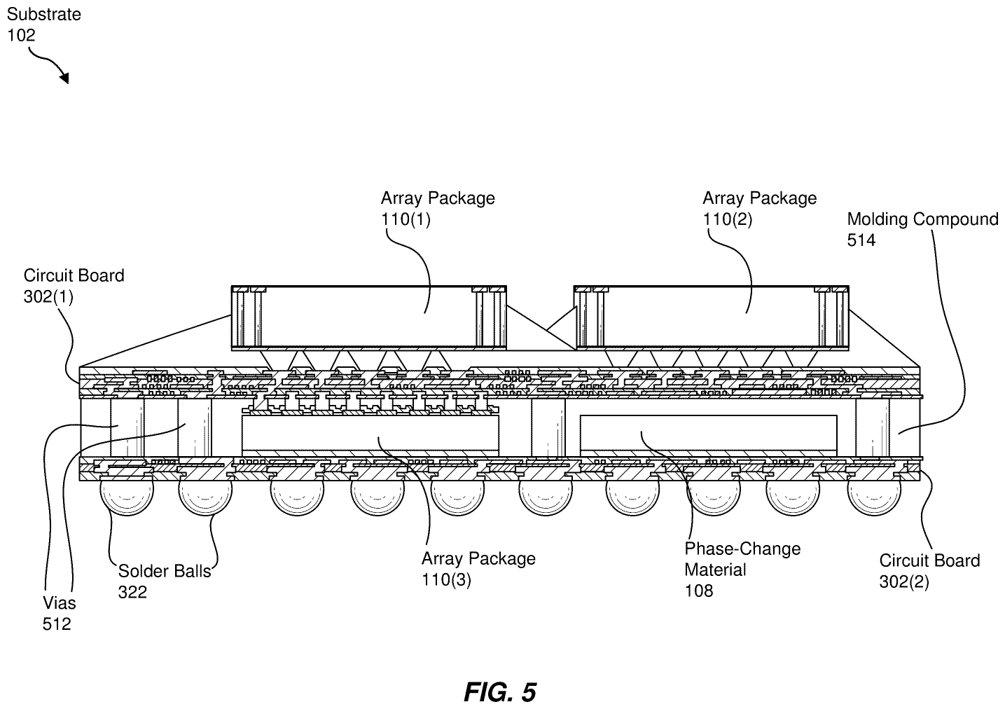

In FIG. 5, the implementation of substrate 102 may include and/or incorporate phase-change material 108 in the area and/or coupling between circuit boards 302(1) and 302(2). For example, a molding compound 514 may be applied and/or installed between circuit boards 302(1) and 302(2) to fill a gap and/or space in that area. In this example, phase-change material 108 may be embedded and/or incorporated into molding compound 514 to support storing thermal energy released by display elements disposed on array package 110(3). Additionally or alternatively, phase-change material 108 may be dispersed throughout molding compound 514 that fills the gap and/or space between circuit boards 302(1) and 302(2).

In the implementation illustrated in FIG. 5, substrate 102 may exclude and/or omit dummy package 310. In place and/or lieu of dummy package 310, substrate 102 may include and/or incorporate phase-change material 108. In some examples, phase-change material 108 may be shaped and/or contoured to mimic the form factor of one of array packages 110(1)-(3) and/or dummy package 310. In such examples, phase-change material 108 may be applied and/or installed between circuit boards 302(1) and 302(2). Additionally or alternatively, molding compound 514 may wholly and/or partially encapsulate and/or surround phase-change material 108 as applied and/or installed between circuit boards 302(1) and 302(2).

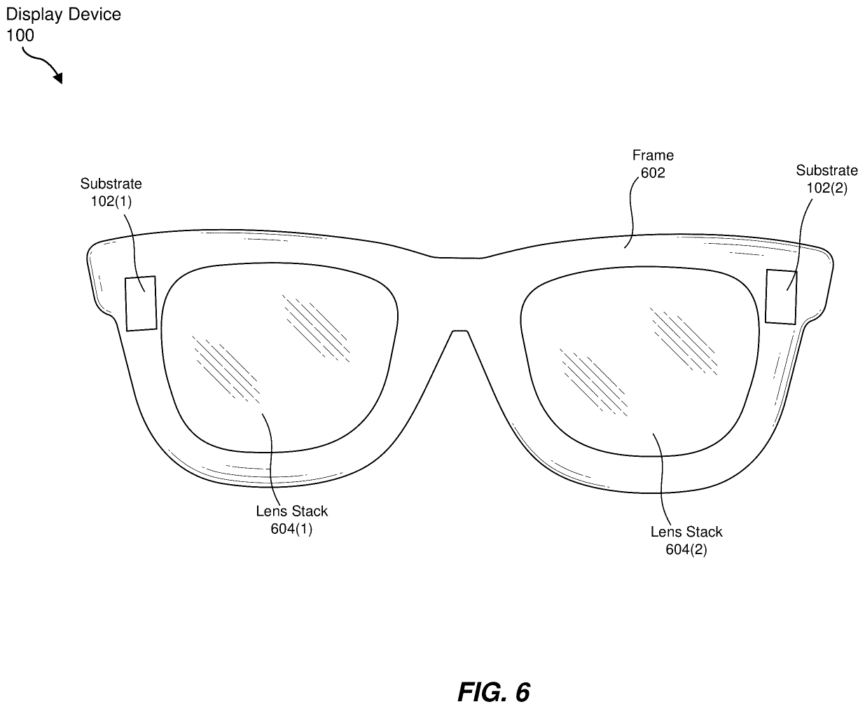

FIG. 6 illustrates an exemplary implementation of display device 100 that includes and/or represents a frame 602, lens stacks 604(1) and 604(2), and/or circuit board assemblies 102(1) and 102(2). In some examples, display device 100 may include and/or represent a pair of AR glasses that integrate real and/or virtual features or elements for viewing by a user. In such examples, frame 602 may be dimensioned to be worn on and/or mounted to the user's head. As illustrated in FIG. 6, lens stacks 604(1) and 604(2) may be coupled and/or secured to frame 602. In one example, lens stacks 604(1) and 604(2) may be positioned and/or placed in an optical path of the user. In this example, the positioning and/or placement of lens stacks 604(1) and 604(2) in the optical path may enable the user to see through at least a portion of lens stacks 604(1) and 604(2) when frame 602 is worn on and/or mounted to the head of the user.

In some examples, lens stacks 604(1) and 604(2) may include and/or represent various optical components that facilitate and/or support one or more features and/or functionalities of display device 100. For example, lens stacks 604(1) and 604(2) may include and/or represent one or more lenses and/or optical waveguides. In one example, each optical waveguide may be configured to display and/or present computer-generated content to the user. In this example, each optical waveguide may be at least partially aligned with a corresponding lens of display device 100 to support and/or facilitate viewing of such computer-generated content in the user's optical path.

In some examples, one or more of circuit board assemblies 102(1) and 102(2) may be embedded and/or installed in frame 602. For example, circuit board assemblies 102(1) and 102(2) may be fixed, secured, and/or coupled to the inside of frame 602. In one example, circuit board assemblies 102(1) and 102(2) may be optically coupled to lens stacks 604(1) and 604(2), respectively, via one or more waveguides. In this example, the waveguides may channel, direct, and/or feed light generated by display elements on circuit board assemblies 102(1) and 102(2) to lens stacks 604(1) and 604(2).

In some examples, display device 100 may refer to and/or represent any type of display and/or visual device that is worn on and/or mounted to a user's head or face. In one example, display device 100 may include and/or represent a pair of AR glasses designed to be worn on and/or secured to a user's head or face. In one example, display device 100 may include and/or incorporate lenses that form a display screen and/or corresponding partially see-through areas. Additionally or alternatively, display device 100 may include and/or incorporate one or more cameras directed and/or aimed toward the user's line of sight and/or field of view.

In some examples, frame 602 may be sized and/or shaped in any suitable way to fit on and/or mount to the head and/or face of a user. In one example, frame 602 may be opaque to radio frequencies and/or visible light. Frame 602 may include and/or contain any of a variety of different materials. For example, frame 602 may be made of magnesium alloy, carbon fiber composite, and/or titanium. Additional examples of such materials include, without limitation, metals, coppers, aluminums, steels, silvers, golds, platinums, plastics, ceramics, polymers, composites, rubbers, nylons, polycarbonates, variations or combinations of one or more of the same, and/or any other suitable materials.

In some examples, lens stacks 604(1) and 604(2) may each be sized and/or shaped in any suitable way to fit in and/or secure to frame 602. In one example, lens stacks 604(1) and 604(2) may include and/or represent a prescription and/or corrective lens intended to correct and/or mitigate one or more refractive errors or imperfections in the user's vision. Lens stacks 604(1) and 604(2) may include and/or contain any of a variety of different materials. Examples of such materials include, without limitation, plastics, glasses (e.g., crown glass), polycarbonates, combinations or variations of one or more of the same, and/or any other suitable materials.

In some examples, circuit board assemblies 102(1) and 102(2) may each be sized and/or shaped in any suitable way for placement and/or insertion within frame 602. In one example, circuit board assemblies 102(1) and 102(2) may each include and/or represent insulating material that facilitates mounting (e.g., mechanical support) and/or interconnection (e.g., electrical and/or optical coupling) of electrical and/or optical components. For example, circuit board assemblies 102(1) and 102(2) may include and/or represent one or more PCBs shaped and/or contoured for installation within the front frame and/or temples of frame 602.

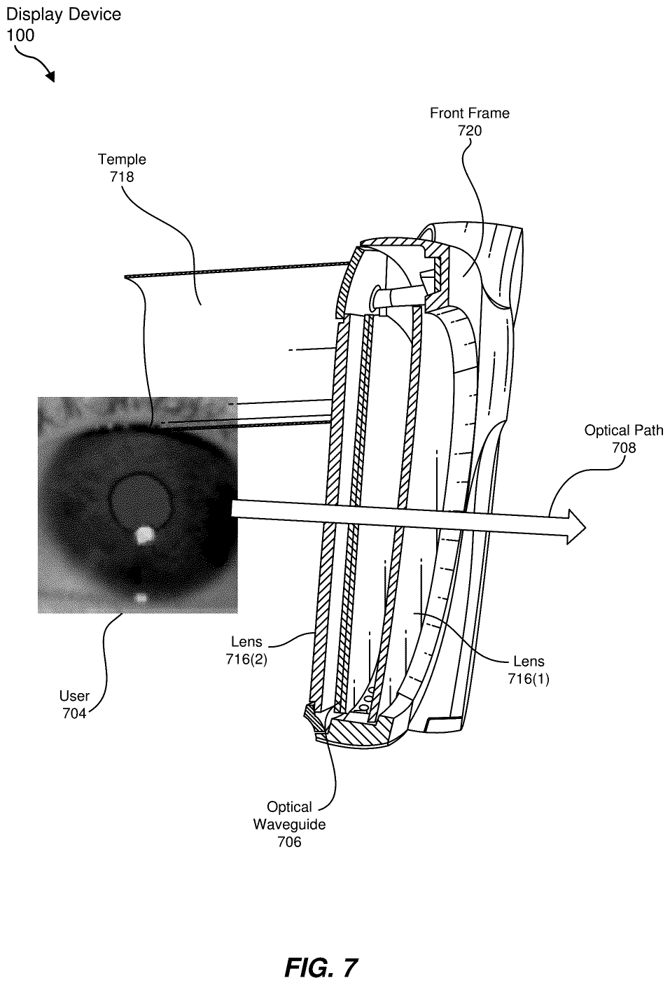

In some examples, display device 100 may include and/or represent one or more additional components, devices, and/or mechanisms that are not necessarily illustrated and/or labelled in FIGS. 1-7. For example, display device 100 may include and/or represent one or more processors and/or memory devices that are not necessarily illustrated and/or labelled in FIG. 6 or 7. Such processors may include and/or represent any type or form of hardware-implemented processing device capable of interpreting and/or executing computer-readable instructions. In one example, such processors may access, modify, and/or execute certain software and/or firmware modules in connection with computer-generated content and/or RF communications. Examples of such processors include, without limitation, physical processors, Central Processing Units (CPUs), microprocessors, microcontrollers, Field-Programmable Gate Arrays (FPGAs) that implement softcore processors, Application-Specific Integrated Circuits (ASICs), portions of one or more of the same, variations or combinations of one or more of the same, and/or any other suitable processing devices.

In some examples, display device 100 may include and/or represent one or more memory devices that store software and/or firmware modules or data that facilitate and/or support AR displays and/or presentations, RF communications, and/or corresponding computing tasks. Such memory devices may include and/or store computer-executable instructions that, when executed by processors, cause the processors to perform one or more tasks in connection with AR displays, environments, and/or contexts.

In some examples, such memory devices may include and/or represent any type or form of volatile or non-volatile storage device or medium capable of storing data and/or computer-readable instructions. In one example, such memory devices may store, load, and/or maintain one or more modules and/or trained inferential models that perform certain tasks, classifications, and/or determinations in connection with AR content and/or RF communications. Examples of such memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, and/or any other suitable storage memory.

FIG. 7 illustrates an exemplary cross section of display device 100. In some examples, frame 602 of display device 100 may include and/or represent a front frame 720 and a temple 218. In such examples, lens stack 604(1) may include and/or represent a pair of lenses 716(1) and 716(2) and/or an optical waveguide 706. In one example, lenses 716(1) and 716(2) and/or optical waveguide 706 may be positioned in an optical path 708 of a user 704 who is wearing display device 100. With lens stack 604(1) in this position, user 704 may be able to see through at least a portion of lens stack 604(1) via optical path 708.

In some examples, optical waveguide 706 may be configured to display computer-generated content to user 704. In one example, optical waveguide 706 may be at least partially aligned with lenses 716(1) and 716(2) along optical path 708. As illustrated in FIG. 7, lens 716(2) may be positioned closer to the head of the user relative to lens 716(1). Put differently, lens 716(1) may be positioned further from the head of the user relative to lens 716(2).

In some examples, optical waveguide 706 may be positioned and/or placed between lenses 716(1) and 716(2) within lens stack 604(1). In one example, optical waveguide 706 may be optically coupled to substrate 102(1). In this example, display elements on circuit board assembly may emit and/or produce visual light that is directed, channeled, and/or fed via optical waveguide 706 to the user for viewing.

In some examples, although not necessarily illustrated and/or labelled in this way in FIGS. 1-7, display device 100 may include and/or represent additional circuitry, transistors, resistors, capacitors, diodes, transceivers, sockets, wiring, circuit boards, power sources, batteries, cabling, light sources, displays, lenses, waveguides, and/or connectors, among other components. Additionally or alternatively, display device 100 may exclude and/or omit one or more of the components, devices, features, and/or mechanisms that are illustrated and/or labelled in FIGS. 1-7. For example, in alternative implementations, display device 100 may exclude and/or omit substrate 102(2).

FIG. 9 illustrates an exemplary profile 900 of phase-change material 108. As illustrated in FIG. 9, exemplary profile 900 may include and/or represent a graphical representation of the relationship between the amount of thermal energy stored by phase-change material 108 and the temperature of phase-change material 108. In other words, exemplary profile 900 may demonstrate and/or represent the effect that different amounts of thermal energy stored by phase-change material 108 have on the temperature of phase-change material 108. Additionally or alternatively, exemplary profile 900 may demonstrate the behavior and/or temperature response of phase-change material 108 when different amounts of thermal energy are applied to phase-change material 108.

In some examples, profile 900 may show and/or demonstrate different rates of temperature change exhibited and/or experienced by phase-change material 108 over different fundamental states and/or a phase transition. For example, while phase-change material 108 is in a solid state, the temperature of phase-change material 108 may change by a rate 902 as different amounts of thermal energy are applied and/or stored. In this example, rate 902 may constitute and/or represent the rate of temperature change experienced by phase-change material 108 as different amounts of thermal energy are applied to and/or stored by phase-change material 108 while in the solid state.

Similarly, while phase-change material 108 is in a liquid state, the temperature of phase-change material 108 may change by a rate 906 as different amounts of thermal energy are applied and/or stored. In this example, rate 906 may constitute and/or represent the rate of temperature change experienced by phase-change material 108 as different amounts of thermal energy are applied to and/or stored by phase-change material 108 while in the liquid state.

In some examples, while phase-change material 108 transitions from solid to liquid (or vice versa), the temperature of phase-change material 108 may change by a rate 904 as different amounts of thermal energy are applied and/or stored. In one example, rate 904 may constitute and/or represent the rate of temperature change experienced by phase-change material 108 as different amounts of thermal energy are applied to and/or stored by phase-change material 108 while undergoing this phase transition.

In some examples, rates 902 and 906 may be similar and/or identical to one another. In other examples, rates 902 and 906 may differ from one another. In one example, rate 904 may differ from both of rates 902 and 906. In this example, rate 904 may indicate and/or demonstrate that the temperature of phase-change material 108 changes much slower and/or much less (if at all) as different amounts of thermal energy are applied to and/or stored by phase-change material 108 while undergoing the phase transition from solid to liquid (or vice versa).

FIG. 8 is a flow diagram of an exemplary method 800 for achieving brightness uniformity across display elements. In one example, the steps shown in FIG. 8 may be performed during the manufacture and/or assembly of a display device and/or a subcomponent of a display device. Additionally or alternatively, the steps shown in FIG. 8 may incorporate and/or involve various sub-steps and/or variations consistent with one or more of the descriptions provided above in connection with FIGS. 1-7 and 9.

As illustrated in FIG. 8, method 800 may include and/or involve the step of disposing, on a circuit board assembly, a set of display elements configured to emit light for presentation to a user (810). Step 810 may be performed in a variety of ways, including any of those described above in connection with FIGS. 1-7 and 9. For example, an AR equipment manufacturer and/or contractor may dispose, on a circuit board assembly, a set of display elements configured to emit light for presentation to a user.

In some examples, method 800 may also include and/or involve the step of applying, to the circuit board assembly or the set of display elements, a phase-change material configured to store thermal energy generated by the set of display elements (820). Step 820 may be performed in a variety of ways, including any of those described above in connection with FIGS. 1-7 and 9. For example, an AR equipment manufacturer and/or contractor may apply, to the circuit board assembly or the set of display elements, a phase-change material configured to store thermal energy generated by the set of display elements.

In some examples, method 800 may also include and/or involve the step of installing the circuit board assembly with the phase-change material into a display device dimensioned to be worn by the user (830). Step 830 may be performed in a variety of ways, including any of those described above in connection with FIGS. 1-7 and 9. For example, an AR equipment manufacturer and/or contractor may install the circuit board assembly with the phase-change material into a display device dimensioned to be worn by the user.

### EXAMPLE EMBODIMENTS

Example 1: A display device comprising (1) a circuit board assembly, (2) a set of display elements disposed on the circuit board assembly and configured to emit light for presentation to a user, and (3) a phase-change material applied to the circuit board assembly or the set of display elements, wherein the phase-change material is configured to store thermal energy generated by the set of display elements.

Example 2: The display device of Example 1, wherein at least one display element included in the set of display elements comprises a semiconductor die mounted between a lens and a heat slug, the phase-change material forming at least a portion of the heat slug.

Example 3: The display device of Example 1 or 2, further comprising an array package coupled to the circuit board assembly, the array package including the set of display elements and at least one via filled with the phase-change material.

Example 4: The display device of any of Examples 1-3, wherein the via is plated with conductive material to provide electrical continuity from one side of the via to another side of the via.

Example 5: The display device of any of Examples 1-4, further comprising an underfill applied between the set of display elements and the circuit board assembly, the phase-change material forming at least a portion of the underfill.

Example 6: The display device of any of Examples 1-5, wherein the underfill comprises (1) an adhesive and (2) one or more beads formed from the phase-change material and incorporated in the adhesive.

Example 7: The display device of any of Examples 1-6, wherein the circuit board assembly comprises (1) a plurality of circuit boards coupled to one another and (2) a molding compound that fills a gap between the plurality of circuit boards, the phase-change material being embedded in the molding compound.

Example 8: The display device of any of Examples 1-7, wherein (1) the set of display elements are packaged as one or more discrete arrays each having a certain form factor, and (2) the phase-change material is shaped to mimic the form factor of the one or more discrete arrays, the phase-change material being installed between the plurality of circuit boards and at least partially encapsulated by the molding compound.

Example 9: The display device of any of Examples 1-8, wherein the phase-change material is dispersed throughout the molding compound that fills the gap between the plurality of circuit boards.

Example 10: The display device of any of Examples 1-9, wherein the set of display elements comprises a microscopic light-emitting diode (microLED) and/or the set of display elements are implemented as a microLED display module.

Example 11: The display device of any of Examples 1-10, further comprising (1) a frame dimensioned to be worn on a head of the user, (2) a lens stack coupled to the frame and positioned in an optical path of the user such that the user is able to see through at least a portion of the lens stack, and (3) a waveguide coupled between the set of display elements and a certain location of the lens stack such that the waveguide directs the light emitted by the set of display elements to the certain location of the lens stack for presentation to the user.

Example 12: The display device of any of Examples 1-11, wherein the phase-change material is configured to (1) experience a temperature change at a first rate relative to an amount of thermal energy stored while in a fundamental state and (2) experience the temperature change at a second rate relative to the amount of thermal energy stored while in a phase transition, wherein the first rate is higher than the second rate.

Example 13: The display device of any of Examples 1-12, wherein the phase-change material is configured to maintain a substantially static temperature despite an increase in the amount of thermal energy stored by the phase-change material during the phase transition.

Example 14: A thermal-storage system comprising (1) a circuit board assembly, (2) a set of display elements disposed on the circuit board assembly and configured to emit light for presentation to a user, and (3) a phase-change material applied to the circuit board assembly or the set of display elements, wherein the phase-change material is configured to (A) store thermal energy generated by the set of display elements and (B) maintain a substantially static temperature despite an increase in the amount of thermal energy stored by the phase-change material during a phase transition.

Example 15: The thermal-storage system of any of Examples 1-14, wherein at least one display element included in the set of display elements comprises a semiconductor die mounted between a lens and a heat slug, the phase-change material forming at least a portion of the heat slug.

Example 16: The thermal-storage system of any of Examples 1-15, further comprising an array package coupled to the circuit board assembly, the array package including (1) the set of display element and (2) at least one via filled with the phase-change material.

Example 17: The thermal-storage system of any of Examples 1-16, wherein the via is plated with conductive material to provide electrical continuity from one side of the via to another side of the via.

Example 18: The thermal-storage system of any of Examples 1-17, further comprising an underfill applied between the set of display elements and the circuit board assembly, the phase-change material forming at least a portion of the underfill.

Example 19: The thermal-storage system of claim 18, wherein the underfill comprises (1) an adhesive and (2) one or more beads formed from the phase-change material and incorporated in the adhesive.

Example 20: A method comprising (1) disposing, on a circuit board assembly, a set of display elements configured to emit light for presentation to a user, (2) applying, to the circuit board assembly or the set of display elements, a phase-change material configured to store thermal energy generated by the set of display elements, and (3) installing the circuit board assembly with the phase-change material into a display device dimensioned to be worn by the user.

Embodiments of the present disclosure may include or be implemented in conjunction with various types of artificial-reality systems. Artificial reality is a form of reality that has been adjusted in some manner before presentation to a user, which may include, for example, a virtual reality, an AR, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a 3D effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

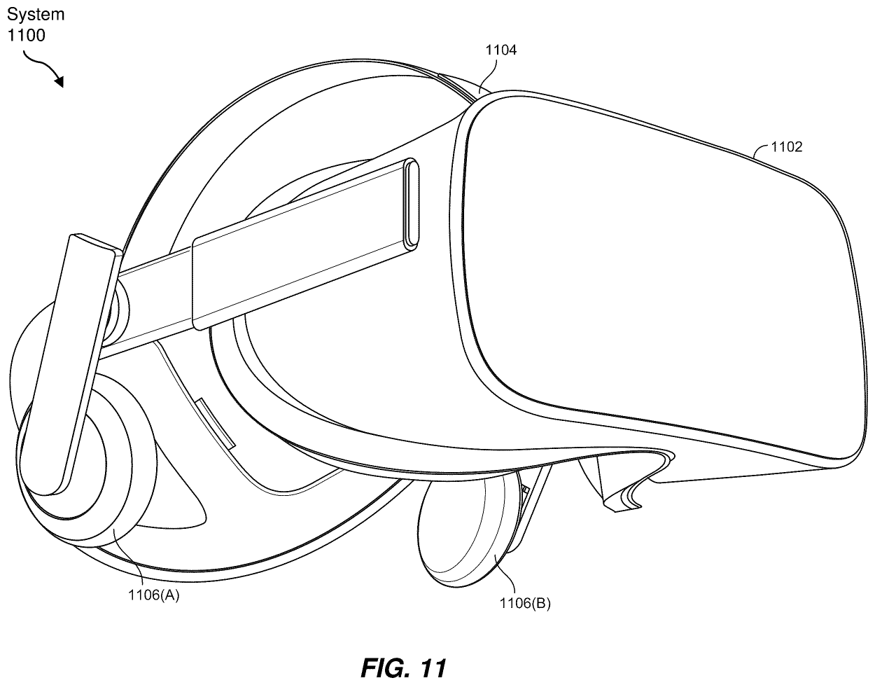

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., AR system 1000 in FIG. 10) or that visually immerses a user in an artificial reality (such as, e.g., virtual-reality system 1100 in FIG. 11). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 10, AR system 1000 may include an eyewear device 1002 with a frame 1010 configured to hold a left display device 1015(A) and a right display device 1015(B) in front of a user's eyes. Display devices 1015(A) and 1015(B) may act together or independently to present an image or series of images to a user. While AR system 1000 includes two displays, embodiments of this disclosure may be implemented in AR systems with a single NED or more than two NEDs.

In some embodiments, AR system 1000 may include one or more sensors, such as sensor 1040. Sensor 1040 may generate measurement signals in response to motion of AR system 1000 and may be located on substantially any portion of frame 1010. Sensor 1040 may represent one or more of a variety of different sensing mechanisms, such as a position sensor, an inertial measurement unit (IMU), a depth camera assembly, a structured light emitter and/or detector, or any combination thereof. In some embodiments, AR system 1000 may or may not include sensor 1040 or may include more than one sensor. In embodiments in which sensor 1040 includes an IMU, the IMU may generate calibration data based on measurement signals from sensor 1040. Examples of sensor 1040 may include, without limitation, accelerometers, gyroscopes, magnetometers, other suitable types of sensors that detect motion, sensors used for error correction of the IMU, or some combination thereof.

In some examples, AR system 1000 may also include a microphone array with a plurality of acoustic transducers 1020(A)-1020(J), referred to collectively as acoustic transducers 1020. Acoustic transducers 1020 may represent transducers that detect air pressure variations induced by sound waves. Each acoustic transducer 1020 may be configured to detect sound and convert the detected sound into an electronic format (e.g., an analog or digital format). The microphone array in FIG. 10 may include, for example, ten acoustic transducers: 1020(A) and 1020(B), which may be designed to be placed inside a corresponding ear of the user, acoustic transducers 1020(C), 1020(D), 1020(E), 1020(F), 1020(G), and 1020(H), which may be positioned at various locations on frame 1010, and/or acoustic transducers 1020(I) and 1020(J), which may be positioned on a corresponding neckband 1005.

In some embodiments, one or more of acoustic transducers 1020(A)-(J) may be used as output transducers (e.g., speakers). For example, acoustic transducers 1020(A) and/or 1020(B) may be earbuds or any other suitable type of headphone or speaker.

The configuration of acoustic transducers 1020 of the microphone array may vary. While AR system 1000 is shown in FIG. 10 as having ten acoustic transducers 1020, the number of acoustic transducers 1020 may be greater or less than ten. In some embodiments, using higher numbers of acoustic transducers 1020 may increase the amount of audio information collected and/or the sensitivity and accuracy of the audio information. In contrast, using a lower number of acoustic transducers 1020 may decrease the computing power required by an associated controller 1050 to process the collected audio information. In addition, the position of each acoustic transducer 1020 of the microphone array may vary. For example, the position of an acoustic transducer 1020 may include a defined position on the user, a defined coordinate on frame 1010, an orientation associated with each acoustic transducer 1020, or some combination thereof.

Acoustic transducers 1020(A) and 1020(B) may be positioned on different parts of the user's ear, such as behind the pinna, behind the tragus, and/or within the auricle or fossa. Or, there may be additional acoustic transducers 1020 on or surrounding the ear in addition to acoustic transducers 1020 inside the ear canal. Having an acoustic transducer 1020 positioned next to an ear canal of a user may enable the microphone array to collect information on how sounds arrive at the ear canal. By positioning at least two of acoustic transducers 1020 on either side of a user's head (e.g., as binaural microphones), AR system 1000 may simulate binaural hearing and capture a 3D stereo sound field around a user's head. In some embodiments, acoustic transducers 1020(A) and 1020(B) may be connected to AR system 1000 via a wired connection 1030, and in other embodiments acoustic transducers 1020(A) and 1020(B) may be connected to AR system 1000 via a wireless connection (e.g., a BLUETOOTH connection). In still other embodiments, acoustic transducers 1020(A) and 1020(B) may not be used at all in conjunction with AR system 1000.

Acoustic transducers 1020 on frame 1010 may be positioned in a variety of different ways, including along the length of the temples, across the bridge, above or below display devices 1015(A) and 1015(B), or some combination thereof. Acoustic transducers 1020 may also be oriented such that the microphone array is able to detect sounds in a wide range of directions surrounding the user wearing AR system 1000. In some embodiments, an optimization process may be performed during manufacturing of AR system 1000 to determine relative positioning of each acoustic transducer 1020 in the microphone array.

In some examples, AR system 1000 may include or be connected to an external device (e.g., a paired device), such as neckband 1005. Neckband 1005 generally represents any type or form of paired device. Thus, the following discussion of neckband 1005 may also apply to various other paired devices, such as charging cases, smart watches, smart phones, wrist bands, other wearable devices, hand-held controllers, tablet computers, laptop computers, other external compute devices, etc.

As shown, neckband 1005 may be coupled to eyewear device 1002 via one or more connectors. The connectors may be wired or wireless and may include electrical and/or non-electrical (e.g., structural) components. In some cases, eyewear device 1002 and neckband 1005 may operate independently without any wired or wireless connection between them. While FIG. 10 illustrates the components of eyewear device 1002 and neckband 1005 in example locations on eyewear device 1002 and neckband 1005, the components may be located elsewhere and/or distributed differently on eyewear device 1002 and/or neckband 1005. In some embodiments, the components of eyewear device 1002 and neckband 1005 may be located on one or more additional peripheral devices paired with eyewear device 1002, neckband 1005, or some combination thereof.

Pairing external devices, such as neckband 1005, with AR eyewear devices may enable the eyewear devices to achieve the form factor of a pair of glasses while still providing sufficient battery and computation power for expanded capabilities. Some or all of the battery power, computational resources, and/or additional features of AR system 1000 may be provided by a paired device or shared between a paired device and an eyewear device, thus reducing the weight, heat profile, and form factor of the eyewear device overall while still retaining desired functionality. For example, neckband 1005 may allow components that would otherwise be included on an eyewear device to be included in neckband 1005 since users may tolerate a heavier weight load on their shoulders than they would tolerate on their heads. Neckband 1005 may also have a larger surface area over which to diffuse and disperse heat to the ambient environment. Thus, neckband 1005 may allow for greater battery and computation capacity than might otherwise have been possible on a stand-alone eyewear device. Since weight carried in neckband 1005 may be less invasive to a user than weight carried in eyewear device 1002, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1005 may be communicatively coupled with eyewear device 1002 and/or to other devices. These other devices may provide certain functions (e.g., tracking, localizing, depth mapping, processing, storage, etc.) to AR system 1000. In the embodiment of FIG. 10, neckband 1005 may include two acoustic transducers (e.g., 1020(I) and 1020(J)) that are part of the microphone array (or potentially form their own microphone subarray). Neckband 1005 may also include a controller 1025 and a power source 1035.

Acoustic transducers 1020(I) and 1020(J) of neckband 1005 may be configured to detect sound and convert the detected sound into an electronic format (analog or digital). In the embodiment of FIG. 10, acoustic transducers 1020(I) and 1020(J) may be positioned on neckband 1005, thereby increasing the distance between the neckband acoustic transducers 1020(I) and 1020(J) and other acoustic transducers 1020 positioned on eyewear device 1002. In some cases, increasing the distance between acoustic transducers 1020 of the microphone array may improve the accuracy of beamforming performed via the microphone array. For example, if a sound is detected by acoustic transducers 1020(C) and 1020(D) and the distance between acoustic transducers 1020(C) and 1020(D) is greater than, e.g., the distance between acoustic transducers 1020(D) and 1020(E), the determined source location of the detected sound may be more accurate than if the sound had been detected by acoustic transducers 1020(D) and 1020(E).

Controller 1025 of neckband 1005 may process information generated by the sensors on neckband 1005 and/or AR system 1000. For example, controller 1025 may process information from the microphone array that describes sounds detected by the microphone array. For each detected sound, controller 1025 may perform a direction-of-arrival (DOA) estimation to estimate a direction from which the detected sound arrived at the microphone array. As the microphone array detects sounds, controller 1025 may populate an audio data set with the information. In embodiments in which AR system 1000 includes an inertial measurement unit, controller 1025 may compute all inertial and spatial calculations from the IMU located on eyewear device 1002. A connector may convey information between AR system 1000 and neckband 1005 and between AR system 1000 and controller 1025. The information may be in the form of optical data, electrical data, wireless data, or any other transmittable data form. Moving the processing of information generated by AR system 1000 to neckband 1005 may reduce weight and heat in eyewear device 1002, making it more comfortable for the user.

Power source 1035 in neckband 1005 may provide power to eyewear device 1002 and/or to neckband 1005. Power source 1035 may include, without limitation, lithium-ion batteries, lithium-polymer batteries, primary lithium batteries, alkaline batteries, or any other form of power storage. In some cases, power source 1035 may be a wired power source. Including power source 1035 on neckband 1005 instead of on eyewear device 1002 may help better distribute the weight and heat generated by power source 1035.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1100 in FIG. 11, that mostly or completely covers a user's field of view. Virtual-reality system 1100 may include a front rigid body 1102 and a band 1104 shaped to fit around a user's head. Virtual-reality system 1100 may also include output audio transducers 1106(A) and 1106(B). Furthermore, while not shown in FIG. 11, front rigid body 1102 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in AR system 1000 and/or virtual-reality system 1100 may include one or more liquid crystal displays (LCDs), light-emitting diode (LED) displays, microLED displays, organic LED (OLED) displays, digital light projector (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in AR system 1000 and/or virtual-reality system 1100 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, AR system 1000 and/or virtual-reality system 1100 may include one or more optical sensors, such as 2D or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, bodysuits, handheld controllers, environmental devices (e.g., chairs, floor mats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A display device comprising:
a substrate;
a set of display elements disposed on the substrate and configured to emit light for presentation to a user; and
a phase-change material applied to the substrate or the set of display elements, wherein the phase-change material is configured to store thermal energy generated by the set of display elements.

2. The display device of claim 1, wherein at least one display element included in the set of display elements comprises a semiconductor die mounted between a lens and a heat slug, the phase-change material forming at least a portion of the heat slug.

3. The display device of claim 1, further comprising an array package coupled to the substrate, the array package including:
the set of display elements; and
at least one via filled with the phase-change material.

4. The display device of claim 3, wherein the via is plated with conductive material to provide electrical continuity from one side of the via to another side of the via.

5. The display device of claim 1, further comprising an underfill applied between the set of display elements and the substrate, the phase-change material forming at least a portion of the underfill.

6. The display device of claim 5, wherein the underfill comprises:
an adhesive; and
one or more beads formed from the phase-change material and incorporated in the adhesive.

7. The display device of claim 1, wherein the substrate comprises:
a plurality of circuit boards coupled to one another; and
a molding compound that fills a gap between the plurality of circuit boards, the phase-change material being embedded in the molding compound.

8. The display device of claim 7, wherein:
the set of display elements are packaged as one or more discrete arrays each having a certain form factor; and
the phase-change material is shaped to mimic the certain form factor of the one or more discrete arrays, the phase-change material being installed between the plurality of circuit boards and at least partially encapsulated by the molding compound.

9. The display device of claim 7, wherein the phase-change material is dispersed throughout the molding compound that fills the gap between the plurality of circuit boards.

10. The display device of claim 1, wherein:
the set of display elements comprises a microscopic light-emitting diode (microLED); or
the set of display elements are implemented as a microLED display module.

11. The display device of claim 1, further comprising:
a frame dimensioned to be worn on a head of the user;
a lens stack coupled to the frame and positioned in an optical path of the user such that the user is able to see through at least a portion of the lens stack; and
a waveguide coupled between the set of display elements and a certain location of the lens stack such that the waveguide directs the light emitted by the set of display elements to the certain location of the lens stack for presentation to the user.

12. The display device of claim 1, wherein the phase-change material is configured to:
experience a temperature change at a first rate relative to an amount of thermal energy stored while in a fundamental state; and
experience the temperature change at a second rate relative to the amount of thermal energy stored while in a phase transition, wherein the first rate is higher than the second rate.

13. The display device of claim 12, wherein the phase-change material is configured to maintain a substantially static temperature despite an increase in the amount of thermal energy stored by the phase-change material during the phase transition.

14. A thermal-storage system comprising:
a substrate;
a set of display elements disposed on the substrate and configured to emit light for presentation to a user; and
a phase-change material applied to the substrate or the set of display elements, wherein the phase-change material is configured to:
store thermal energy generated by the set of display elements; and
maintain a substantially static temperature despite an increase in an amount of thermal energy stored by the phase-change material during a phase transition.

15. The thermal-storage system of claim 14, wherein at least one display element included in the set of display elements comprises a semiconductor die mounted between a lens and a heat slug, the phase-change material forming at least a portion of the heat slug.

16. The thermal-storage system of claim 14, further comprising an array package coupled to the substrate, the array package including:
the set of display elements; and
at least one via filled with the phase-change material.

17. The thermal-storage system of claim 16, wherein the via is plated with conductive material to provide electrical continuity from one side of the via to another side of the via.

18. The thermal-storage system of claim 14, further comprising an underfill applied between the set of display elements and the substrate, the phase-change material forming at least a portion of the underfill.

19. The thermal-storage system of claim 18, wherein the underfill comprises:
an adhesive; and
one or more beads formed from the phase-change material and incorporated in the adhesive.

20. A method comprising:
disposing, on a substrate, a set of display elements configured to emit light for presentation to a user;
applying, to the substrate or the set of display elements, a phase-change material configured to store thermal energy generated by the set of display elements; and
installing the substrate with the phase-change material into a display device dimensioned to be worn by the user.
